(19) United States
(12) Patent Application Publication
(10) Pub. No.: US 2026/0282802 A1
(43) Pub. Date: Sep. 17, 2026

(54) SUBSTRATE PROCESSING APPARATUS AND SUBSTRATE TEMPERATURE CONTROL METHOD

(71) Applicant: Tokyo Electron Limited, Tokyo (JP)

(72) Inventor: Masaharu OYA, Miyagi (JP)

(73) Assignee: Tokyo Electron Limited, Tokyo (JP)

(21) Appl. No.: 19/672,778

(22) Filed: May 11, 2026

Related U.S. Application Data
(63) Continuation of application No. PCT/JP2024/044147, filed on Dec. 13, 2024.

(30) Foreign Application Priority Data
Dec. 27, 2023 (JP) 2023-220310

(51) Int. Cl. H10P 72/00; H01J 37/32

(52) U.S. Cl. CPC H10P 72/0432; H01J 37/32724; H01J 2237/2001

(57) ABSTRACT

A substrate processing apparatus includes: a stage for a substrate; a chamber and a heat source that inputs heat to the substrate placed on the stage; a cooling structure located on the stage and cools the stage; a heater that heats the stage, the heater is located between a placement surface of the stage and the cooling structure, the heater to control a heating value; a temperature sensor that measures a temperature of the stage; acquisition circuitry that periodically acquires a heating value of the heater, the temperature of the stage, and a temperature of the cooling structure; prediction circuitry that predicts, from the heating value of the heater, the temperature of the stage, and the temperature of the cooling structure acquired by the acquisition circuitry, a time derivative of the temperature of the stage, and a time derivative of the temperature of the cooling structure.

### CROSS-REFERENCE TO RELATED APPLICATIONS

This application is a continuation of International Application No. PCT/JP2024/044147, filed on Dec. 13, 2024 which claims the benefit of priority of the prior Japanese Patent Application No. 2023-220310, filed on Dec. 27, 2023, the entire contents of each of which are incorporated herein by reference.

### BACKGROUND

### Field

The present disclosure relates to a substrate processing apparatus and a substrate temperature control method.

### Background Art

JP 2008-177285 A discloses “A plasma processing apparatus including: a processing chamber whose inside is evacuated to reduce pressure; a sample stage provided in the processing chamber and having a sample placement surface on which a substrate to be processed is disposed (herein “disposed” means the same as “located”); a plasma generation device for generating plasma in the processing chamber; a heat transfer gas supply system for supplying a heat transfer gas to the sample placement surface; and a refrigerant passage provided in the sample stage and through which a refrigerant circulates, in which the sample stage includes a heater layer provided between the sample placement surface and the refrigerant passage, and the heater layer is formed by being divided into a plurality of regions in a radial direction of the sample placement surface, the plasma processing apparatus further including: temperature monitors each provided in a vicinity of the heater layer in the sample stage at a position corresponding to one of divided regions of the heater layer; and a temperature control device that estimates a temperature of a position corresponding to each of the divided regions of the substrate to be processed placed on the sample placement surface on a basis of temperature information from each of the temperature monitors, and controls power supply to the heater layer of each of the divided regions depending on an estimated value of the temperature”.

### SUMMARY

In an embodiment of a present disclosure, a substrate processing apparatus includes: a stage that supports a substrate; a chamber in which the stage is located and a heat source that inputs heat to the substrate placed on the stage; a cooling structure that is located on the stage and cools the stage; a heater that heats the stage, the heater is located between a placement surface of the stage on which the substrate is placed and the cooling structure, the heater to control a heating value; a temperature sensor that measures a temperature of the stage; acquisition circuitry that periodically acquires a heating value of the heater, the temperature of the stage, and a temperature of the cooling structure; prediction circuitry that predicts, from the heating value of the heater, the temperature of the stage, and the temperature of the cooling structure acquired by the acquisition circuitry, a time derivative of the temperature of the stage, and a time derivative of the temperature of the cooling structure, a temperature of the substrate by using a calculation formula for predicting the temperature of the substrate from the heating value of the heater, the temperature of the stage, the temperature of the cooling structure, the time derivative of the temperature of the stage, and the time derivative of the temperature of the cooling structure; and heat generation controller circuitry that controls the heating value of the heater such that the temperature of the substrate predicted by the prediction circuitry becomes a predetermined temperature.

### BRIEF DESCRIPTION OF DRAWINGS

The scope of the present disclosure is best understood from the following detailed description of exemplary embodiments when read in conjunction with the accompanying drawings.

FIG. 1 is a diagram for explaining a configuration example of a plasma processing apparatus of a capacitively-coupled type;

FIG. 2 is a plan view illustrating an exemplary structure of an electrostatic chuck according to an embodiment;

FIG. 3 is a cross-sectional view illustrating an exemplary structure of the electrostatic chuck according to the embodiment;

FIG. 4 is a block diagram illustrating a schematic configuration of a controller according to the embodiment;

FIG. 5 is a diagram illustrating an example of a thermal circuit representing a substrate and a body according to the embodiment; and

FIG. 6 is a flowchart illustrating an example of a flow of a substrate temperature controlling process according to the embodiment.

### DESCRIPTION OF EMBODIMENTS

Hereinafter, embodiments of a substrate processing apparatus and a substrate temperature control method disclosed herein will be described in detail by referring to the drawings. Note that the substrate processing apparatus and the substrate temperature control method disclosed are not limited by the present embodiments.

Meanwhile, there are known substrate processing apparatuses that perform heat treatment such as plasma processing or ashing on a substrate such as a semiconductor wafer (hereinafter also referred to as “wafer”). In some of such substrate processing apparatuses, a heater is provided to a placement part on which a substrate is placed, a flow path through which a refrigerant flows is formed, and the temperature of the placement part is controlled by heating by the heater and cooling by the refrigerant flowing through the flow path to control the temperature of the substrate.

However, in a substrate processing apparatus, there are cases where heat is input to a substrate from a heat source such as plasma or a heated component in a chamber, and the temperature of the substrate cannot be accurately controlled.

Therefore, in the substrate processing apparatuses, technology for accurately controlling the temperature of a substrate is desired.

### EMBODIMENTS

### Apparatus Configuration

An example of a substrate processing apparatus of the present disclosure will be described. In embodiments described below, a case where the substrate processing apparatus of the present disclosure is a plasma processing system having a system configuration for performing plasma processing will be described as an example.

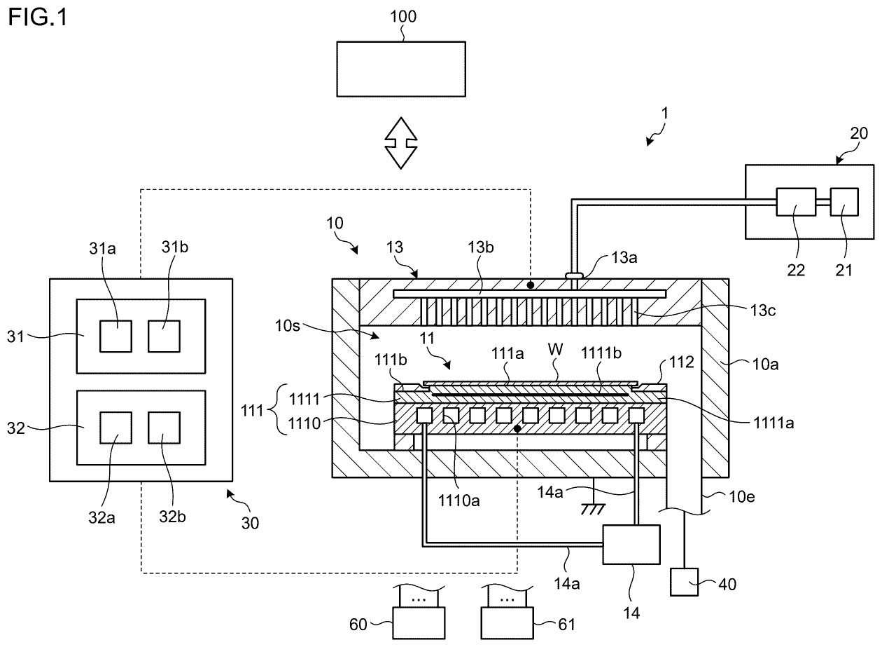

Hereinafter, a configuration example of the plasma processing system will be described. FIG. 1 is a diagram for explaining a configuration example of a plasma processing apparatus of a capacitively-coupled type.

The plasma processing system includes a plasma processing apparatus 1 of the capacitively-coupled type and a controller 100. The plasma processing apparatus 1 of the capacitively-coupled type includes a plasma processing chamber 10, a gas supply unit 20, a power supply 30, and an exhaust system 40 (herein “unit” means the same as “circuitry”). The plasma processing apparatus 1 also includes a substrate support unit 11 and a gas introduction unit. The gas introduction unit introduces at least one type of processing gas into the plasma processing chamber 10. The gas introduction unit includes a showerhead 13. The substrate support unit 11 is disposed in the plasma processing chamber 10. The showerhead 13 is disposed above the substrate support unit 11. In one embodiment, the showerhead 13 constitutes at least a portion of the ceiling of the plasma processing chamber 10. The plasma processing chamber 10 has a plasma processing space 10s defined by the showerhead 13, a side wall 10a of the plasma processing chamber 10, and the substrate support unit 11. The plasma processing chamber 10 has at least one gas supply port for supplying at least one type of processing gas to the plasma processing space 10s and at least one gas discharge port for discharging gas from the plasma processing space. The plasma processing chamber 10 is grounded. The showerhead 13 and the substrate support unit 11 are electrically insulated from a housing of the plasma processing chamber 10.

The substrate support unit 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in plan view. The substrate W is disposed in the central region 111a of the body 111, and the ring assembly 112 is disposed in the annular region 111b of the body 111 in such a manner as to surround the substrate W in the central region 111a of the body 111. Therefore, the central region 111a is also referred to as a substrate support surface for supporting the substrate W, and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Note that another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one radio frequency (RF)/direct current (DC) electrode coupled to an RF power supply 31 and/or a DC power supply 32 described later may be disposed in the ceramic member 1111a. In this case, at least one RF/DC electrode functions as a lower electrode. In a case where a bias RF signal and/or a DC signal described below is supplied to at least one RF/DC electrode, the RF/DC electrode is also referred to as a bias electrode. Note that the conductive member of the base 1110 and at least one RF/DC electrode may function as a plurality of lower electrodes. In addition, the electrostatic electrode 1111b may function as a lower electrode. Therefore, the substrate support unit 11 includes at least one lower electrode.

The ring assembly 112 includes one or a plurality of annular members. In one embodiment, the one or a plurality of annular members include one or a plurality of edge rings and at least one cover ring. The edge ring is formed of a conductive material or an insulating material, and the cover ring is formed of an insulating material.

In addition, the substrate support unit 11 may include a temperature control module that adjusts at least one of the electrostatic chuck 1111, the ring assembly 112, or the substrate W to a target temperature. The temperature control module may include a heater, a heat transfer medium, a flow path 1110a, or a combination thereof. A heat-transfer fluid such as brine or gas flows through the flow path 1110a. In one embodiment, the flow path 1110a is formed in the base 1110, and one or a plurality of heaters are arranged in the ceramic member 1111a of the electrostatic chuck 1111. Pipes 14a are connected to both ends of the flow path 1110a, which is connected to a chiller unit 14 via the pipes 14a. The chiller unit 14 stores, for example, a refrigerant such as brine, and supplies the stored refrigerant to one of the pipes 14a. The refrigerant supplied from the chiller unit 14 is supplied to the flow path 1110a via the pipe 14a, flows from one end to the other end of the flow path 1110a, and returns to the chiller unit 14 via the other pipe 14a. The chiller unit 14 is capable of changing the temperature of the stored refrigerant. The chiller unit 14 incorporates a temperature sensor, and is capable of measuring the temperature of the refrigerant to be supplied. The chiller unit 14 changes the temperature of the stored refrigerant under the control by the controller 100. The chiller unit 14 outputs the temperature of the refrigerant measured by the temperature sensor to the controller 100. The plasma processing apparatus 1 is capable of controlling the temperature of the body 111 by heating the body 111 with the heaters while cooling the body 111 by circulating the refrigerant whose temperature has been controlled from the chiller unit 14 to the flow path 1110a. In the embodiment, the body 111 corresponds to the stage of the present disclosure. In the embodiment, the central region 111a corresponds to the placement surface of the present disclosure. In the embodiment, the refrigerant, the flow path 1110a, and the like correspond to the cooling mechanism of the present disclosure (herein “cooling mechanism” means the same as “cooling structure”).

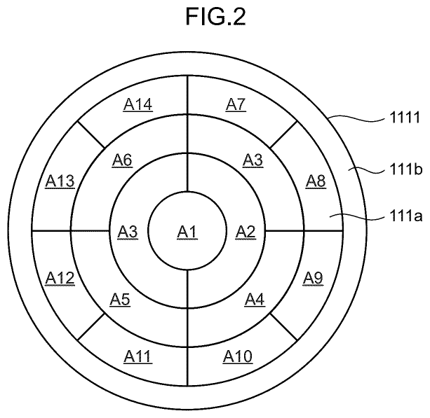

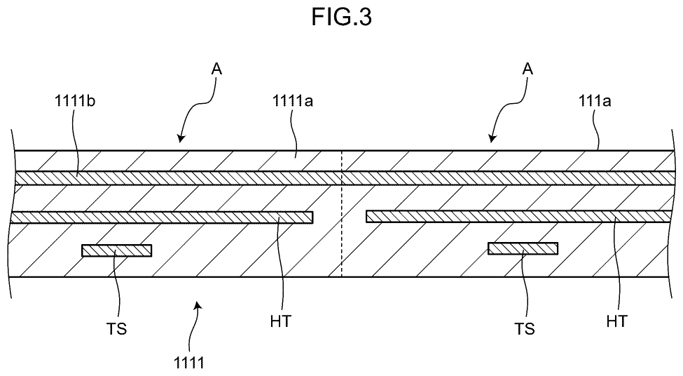

The structure of the electrostatic chuck 1111 of the substrate support unit 11 will be described. FIG. 2 is a plan view illustrating an exemplary structure of the electrostatic chuck 1111 according to the embodiment. FIG. 3 is a cross-sectional view illustrating an exemplary structure of the electrostatic chuck 1111 according to the embodiment.

FIG. 2 is a plan view of an upper surface of the electrostatic chuck 1111. The upper surface of the electrostatic chuck 1111 is divided into the central region 111a and the annular region 111b. The central region 111a is a substantially circular region in plan view. The substrate W is placed on the upper surface of the central region 111a. The diameter of the central region 111a is substantially the same as or slightly smaller than the diameter of the substrate W. The annular region 111b is a region surrounding the central region 111a, and extends in a substantially annular shape. In one embodiment, the upper surface of the annular region 111b is positioned below the upper surface of the central region 111a.

The central region 111a is divided into a plurality of areas A1 to A14. Hereinafter, in a case where the areas A1 to A14 are collectively referred to without distinction, the areas A1 to A14 are referred to as areas A. Each of the areas A is a region obtained by dividing the central region 111a, and constitutes a part of the central region 111a. For example, as illustrated in FIG. 2, the center of the central region 111a is divided into a circular area A1. The central region 111a is divided into a plurality of annular regions concentric from the circular area A1, and each of the plurality of annular regions is divided into a plurality of arc-shaped areas A2 to A14 in the circumferential direction. The arc-shaped areas A2 to A14 are divided such that the closer to the outer periphery, the smaller the angular width is. The flow path 1110a is formed in the base 1110 in such a manner as to pass below all the areas A. Note that the dividing method of the areas A illustrated in FIG. 2 is an example, and the present disclosure is not limited thereto. For example, the central region 111a may be divided such that the width in the radial direction of an arc-shaped area A is narrower as the area A is closer to the outer periphery. Further alternatively, in the central region 111a, regions concentric from the center may be divided into areas A at regular angles. Further alternatively, the central region 111a may be divided into areas A in a lattice pattern. Further alternatively, in order to finely control the temperature distribution in the central region 111a, the central region 111a may be divided into a larger number of areas A. For example, the central region 111a may be divided into one hundred or more areas A. In addition, although a case where the annular region 111b is not divided is described in the dividing method of the areas A illustrated in FIG. 2, the present disclosure is not limited thereto. The annular region 111b may also be divided into a plurality of areas A. For example, the annular region 111b may be divided into a plurality of arc-shaped areas A in the circumferential direction.

In the electrostatic chuck 1111, a heater HT and a temperature sensor TS are provided in each of the areas A. FIG. 3 schematically illustrates a partial cross section of two areas A of the electrostatic chuck 1111. The electrostatic electrode 1111b is disposed in the ceramic member 1111a. In the ceramic member 1111a, a heater HT and a temperature sensor TS are arranged for each area A. A heater HT generates heat by being supplied with power, thereby heating the area A. In the embodiment, the heater HT corresponds to the heating mechanism of the present disclosure. In the embodiment, the temperature sensor TS corresponds to the measuring unit of the present disclosure.

Let us refer back to FIG. 1. Each heater HT is connected to a heater power supply 60. Each temperature sensor TS is connected to a temperature detector 61. Note that in FIG. 1, wiring connecting each heater HT and the heater power supply 60 and wiring connecting each temperature sensor TS and the temperature detector 61 are partially omitted.

The heater power supply 60 supplies power to each heater HT. The heater power supply 60 can adjust power supplied to each heater HT. For example, the heater power supply 60 performs pulse width modulation (PWM) control of power supplied to each heater HT. In the PWM control, power output is controlled by periodically switching between on and off in one cycle. The heater power supply 60 is capable of supplying predetermined power to each heater HT, and controls power to be supplied to each heater HT by changing the ratio (duty ratio) of an ON period within a cycle. The heater power supply 60 adjusts the power to be supplied to each heater HT on the basis of control data input from the controller 100. In each heater HT, the heating value can be controlled by the PWM control of the supplied power. Each heater HT generates heat by the power supplied from the heater power supply 60 and heats the area A.

The temperature detector 61 measures the resistance value of each temperature sensor TS, and detects the temperature of each temperature sensor TS disposed in the respective areas A on the basis of the measured resistance values.

Note that the temperature sensor TS may include a material whose resistance value changes depending on the temperature. The temperature sensor TS is, for example, a thermistor. Furthermore, the temperature sensor TS may be a thin film (herein “film” means the same as “layer”) formed of any of materials containing tungsten, nickel, molybdenum, copper, silver, platinum, or aluminum. The temperature detector 61 may measure the current and the voltage of the power supplied to each temperature sensor TS, obtain the resistance value of the temperature sensor TS from the measured current and voltage, and detect the temperature of the body 111 of the area A on the basis of the obtained resistance value.

The showerhead 13 introduces at least one type of processing gas from the gas supply unit 20 into the plasma processing space 10s. The showerhead 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. The showerhead 13 also includes at least one upper electrode. The gas introduction unit may include, in addition to the showerhead 13, one or a plurality of side gas injectors (SGIs) attached to one or a plurality of openings formed in a side wall 10a.

The gas supply unit 20 may include at least one gas source 21 and at least one flow controller 22. In one embodiment, the gas supply unit 20 supplies at least one type of processing gas from a corresponding gas source 21 to the showerhead 13 via a corresponding flow controller 22. Each flow controller 22 may include, for example, a mass flow controller or a pressure-control type flow controller. Additionally, the gas supply unit 20 may include one or more flow volume modulation devices that modulate or pulse the flow volume of at least one type of processing gas.

The power supply 30 includes an RF power supply 31 coupled to the plasma processing chamber 10 via at least one impedance matching circuit. The RF power supply 31 supplies at least one RF signal (RF power) to at least one lower electrode and/or at least one upper electrode. As a result, plasma is formed from at least one type of processing gas supplied to the plasma processing space 10s. Accordingly, the RF power supply 31 may function as at least a part of a plasma generator that generates plasma from one or more types of processing gases in the plasma processing chamber 10. In addition, by supplying a bias RF signal to at least one lower electrode, a bias potential is generated in the substrate W, whereby an ion component in the formed plasma can be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit and generates a source RF signal (source RF power) for plasma generation. In one embodiment, the source RF signal has a frequency in a range of 10 MHz to 150 MHz. In one embodiment, the first RF generator 31a may generate a plurality of source RF signals having different frequencies. The generated one or more source RF signals are supplied to at least one lower electrode and/or at least one upper electrode.

The second RF generator 31b is coupled to at least one lower electrode via the at least one impedance matching circuit and generates a bias RF signal (bias RF power). The frequency of the bias RF signal may be the same as or different from the frequency of the source RF signal. In one embodiment, the bias RF signal has a lower frequency than the frequency of the source RF signal. In one embodiment, the bias RF signal has a frequency in a range of 100 kHz to 60 MHz. In one embodiment, the second RF generator 31b may generate a plurality of bias RF signals having different frequencies. The generated one or a plurality of bias RF signals are supplied to at least one lower electrode. Furthermore, in various embodiments, at least one of the source RF signal or the bias RF signal may be pulsed.

The power supply 30 may also include a DC power supply 32 coupled to the plasma processing chamber 10. The DC power supply 32 includes a first DC generator 32a and a second DC generator 32b. In an embodiment, the first DC generator 32a is connected to at least one lower electrode and generates a first DC signal. The generated first bias DC signal is applied to at least one lower electrode. In an embodiment, the second DC generator 32b is connected to at least one upper electrode and generates a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from a DC signal is connected between the first DC generator 32a and at least one lower electrode. Therefore, the first DC generator 32a and the waveform generator constitute a voltage pulse generator. In a case where the second DC generator 32b and the waveform generator constitute a voltage pulse generator, the voltage pulse generator is connected to at least one upper electrode. The voltage pulse may have either a positive polarity or a negative polarity. The sequence of voltage pulses may include one or a plurality of positive voltage pulses and one or a plurality of negative voltage pulses in one cycle. Note that the first and second DC generators 32a and 32b may be provided in addition to the RF power supply 31, and the first DC generator 32a may be provided instead of the second RF generator 31b.

The exhaust system 40 can be connected to a gas discharge port 10e provided, for example, at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbomolecular pump, a dry pump, or a combination thereof.

The operation of the plasma processing apparatus 1 configured as described above is integrally controlled by the controller 100 (herein “controller” means the same as “controller circuitry”). The controller 100 is, for example, a computer, and controls each unit of the plasma processing apparatus 1. The operation of the plasma processing apparatus 1 is integrally controlled by the controller 100. The controller 100 performs control to cause the plasma processing apparatus 1 to execute various steps described in the present disclosure.

### Configuration of Controller

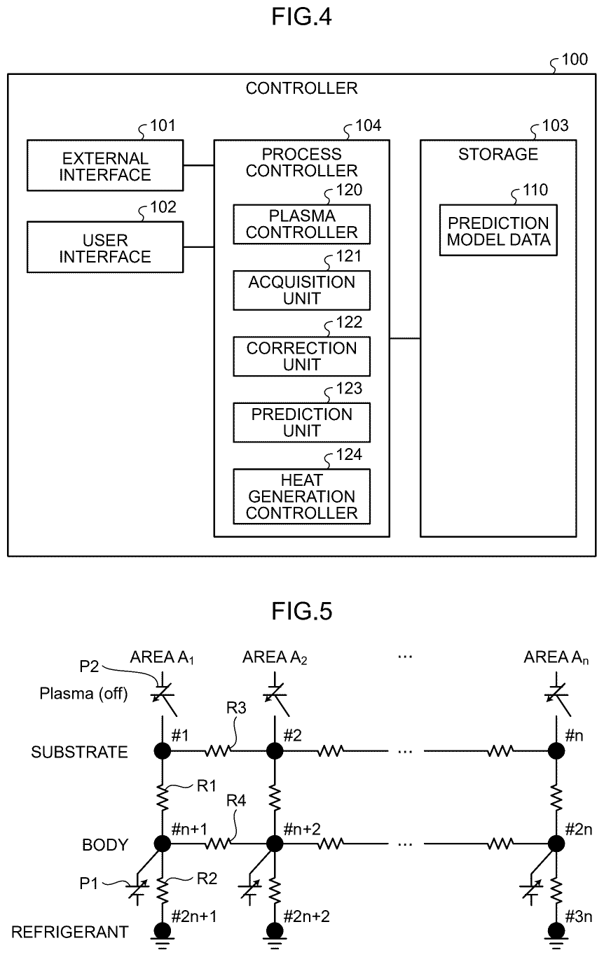

Next, the controller 100 will be described. FIG. 4 is a block diagram illustrating a schematic configuration of the controller 100 according to the embodiment. The controller 100 includes an external interface 101, a user interface 102, a storage 103, and a process controller 104.

The external interface 101 can communicate with each unit of the plasma processing apparatus 1, and receives and outputs various types of data. The user interface 102 includes a keyboard on which a process manager inputs a command to manage the plasma processing apparatus 1, a display that visualizes and displays an operation state of the plasma processing apparatus 1, and the like. The controller/controller circuitry 100 can be programmable circuitry (e.g., embedded processor) or fixed circuitry (e.g., ASIC or PAL). In an exemplary embodiment, the controller/controller circuitry 100 can include one or more programmable processors/controllers.

The storage 103 stores a control program (software) and various programs for implementing various processes executed in the plasma processing apparatus 1 under the control by the process controller 104. In addition, the storage 103 stores various types of data used in a program executed by the process controller 104. For example, the storage 103 stores a recipe in which processing condition data and the like are stored and prediction model data 110. The programs and data to be used may be stored in a computer recording medium (such as a hard disk, an optical disc such as a DVD, a flexible disk, or a semiconductor memory) that can be read by a computer. In addition, the programs and data can be transmitted from another device via, for example, a dedicated line as needed and used online.

The prediction model data 110 is data storing a prediction model that predicts the temperature of the substrate W from the heating values of the heaters HT, the temperature of the body 111, the temperature of the refrigerant, the time derivative of the temperature of the body 111, and the time derivative of the temperature of the refrigerant. In the present embodiment, the prediction model is a calculation formula that predicts the temperature of the substrate W in each area A from the heating value of the heater HT in the area A, the temperature of the body 111, the temperature of the refrigerant, the time derivative of the temperature of the body 111, and the time derivative of the temperature of the refrigerant. Details of the prediction model will be described later.

The process controller 104 includes a processor such as a central processing unit (CPU) or a micro processing unit (MPU) and controls each unit of the plasma processing apparatus 1. The process controller 104 has an internal memory for storing programs and data, reads the control program stored in the storage 103, and executes processing of the read control program. The process controller 104 functions as various processing units by the operation of the control program. For example, the process controller 104 has functions of a plasma controller 120, an acquisition unit 121, a correction unit 122, a prediction unit 123, and a heat generation controller 124 (herein “heat generation controller” means the same as “heat generation controller circuitry”). In the present embodiment, a case where the process controller 104 has the functions of the plasma controller 120, the acquisition unit 121, the correction unit 122, the prediction unit 123, and the heat generation controller 124 will be described as an example. However, the functions of the plasma controller 120, the acquisition unit 121, the correction unit 122, the prediction unit 123, and the heat generation controller 124 may be implemented in a distributed manner by a plurality of controllers.

The plasma controller 120 controls each unit of the plasma processing apparatus 1 to control plasma processing.

The acquisition unit 121 periodically acquires the heating value of each heater HT, the temperature of the body 111, and the temperature of the refrigerant. In the present embodiment, the acquisition unit 121 periodically acquires the temperature of the refrigerant, the heating value of a heater HT for each area A, and the temperature of the body 111.

Details of the correction unit 122 and the prediction unit 123 will be described later.

The heat generation controller 124 controls the heater power supply 60 via the external interface 101 to control the heating value of each heater HT. For example, the heat generation controller 124 outputs control data for specifying power supplied to each heater HT to the heater power supply 60 to control the heating value of each heater HT. In the present embodiment, the heat generation controller 124 outputs control data specifying the duty ratio of each heater HT to the heater power supply 60. The heater power supply 60 supplies power to each heater HT at the specified duty ratio on the basis of the control data. The heater HT generates heat with a heating value corresponding to the supplied power. For example, in a case where power of 100 W per unit time can be supplied to one heater HT and the duty ratio is specified to 20%, the heater power supply 60 controls the duty ratio of the power supplied to the heater HT to 20% and supplies power of 20 W per unit time to the heater HT. In this case, the heater HT generates heat with a heating value of 20 W per unit time.

Next, the flow of the plasma processing will be briefly described.

The substrate W is carried into the plasma processing chamber 10 via a carry-in/out port by a transfer mechanism such as a transfer arm, and is placed in the central region 111a of the substrate support unit 11.

The plasma controller 120 controls plasma processing. For example, the plasma controller 120 controls the exhaust system 40 to exhaust the inside of the plasma processing chamber 10 to a predetermined degree of vacuum. The plasma controller 120 controls the gas supply unit 20 to introduce the processing gas from the gas supply unit 20 into the plasma processing space 10s. The plasma controller 120 controls the power supply 30, supplies the source RF signal and the bias RF signal from the first RF generator 31a and the second RF generator 31b in accordance with the introduction of the processing gas, and generates plasma in the plasma processing chamber 10.

In the plasma processing, the progress of the processing changes depending on the temperature of the substrate W. For example, in plasma etching, the progress rate of etching changes depending on the temperature of the substrate W. Therefore, in the plasma processing apparatus 1, it is conceivable that the temperature of the body 111 is detected by the temperature sensor TS, and that the temperature of the substrate W is controlled by performing feedback control such that the body 111 has a predetermined temperature by heating by the heaters HT and cooling by the refrigerant.

However, the substrate W may receive heat input from a heat source emerging in the plasma processing chamber 10. A heat source is a supply source that supplies heat to the substrate W. Components and spaces having a temperature higher than the temperature of the substrate W in the plasma processing chamber 10 serve as a heat source. A heat source emerges in the plasma processing chamber 10. For example, plasma generated in the plasma processing chamber 10 during the plasma processing serves as a heat source. During the plasma processing, the substrate W receives heat input from the plasma. In addition, a component in the plasma processing chamber 10 becomes a heat source when heated by plasma or the like to a temperature higher than the temperature of the substrate W. The substrate W receives heat input by radiation from the heated component in the plasma processing chamber 10. As described above, there is a case where the plasma processing apparatus 1 cannot accurately control the temperature of the substrate W due to heat input to the substrate W from a heat source such as plasma or a heated component in the plasma processing chamber 10.

Therefore, the plasma processing apparatus 1 according to the present embodiment controls the temperature of the substrate W as follows.

The acquisition unit 121 periodically acquires the heating value of each heater HT, the temperature of the body 111, and the temperature of the refrigerant. In the present embodiment, the acquisition unit 121 periodically acquires the temperature of the refrigerant, the heating value of a heater HT in each area A, and the temperature of the body 111.

For example, the acquisition unit 121 acquires the temperature of each temperature sensor TS disposed in each area A from the temperature detector 61 via the external interface 101 as the temperature of the body 111 in the area A. The acquisition unit 121 acquires the temperature of the refrigerant from the chiller unit 14 via the external interface 101. The temperature of the refrigerant may be acquired from a thermometer installed in a pipe 14a.

The acquisition unit 121 acquires the heating value of a heater HT in each area A from the heat generation controller 124. For example, the acquisition unit 121 acquires, from the heat generation controller 124, power supplied to a heater HT in each area A controlled by the heat generation controller 124. The acquisition unit 121 specifies the acquired power supplied to the heater HT in each area A as the heating value of the heater HT in each area A. In the present embodiment, the acquisition unit 121 acquires the duty ratio of a heater HT in each area A controlled by the heat generation controller 124 from the heat generation controller 124. The acquisition unit 121 obtains the power supplied to a heater HT in each area A from the duty ratio of the heater HT in each area A and the power that can be supplied to the heater HT in each area A by the heater power supply 60. For example, in a case where the duty ratio is 20% and the heater power supply 60 can supply power of 100 W per unit time to a heater HT in an area A, the acquisition unit 121 specifies the power supplied to the heater HT as 20 W per unit time. The acquisition unit 121 specifies the specified value of 20 W per unit time as the heating value of the heater HT.

The correction unit 122 corrects the temperature of the refrigerant acquired by the acquisition unit 121 to the temperature of the refrigerant in each area A along the flow path 1110a.

The prediction unit 123 predicts the temperature of the substrate W in each area A using a prediction model that predicts the temperature of the substrate W.

The prediction model will be described hereinbelow. The prediction model can be expressed as a mathematical model that calculates the temperature of the substrate W in each area A by, for each area A, adding up products obtained by multiplying the heating value of a heater HT, the temperature of the body 111, the temperature of the refrigerant, the time derivative of the temperature of the body 111, and the time derivative of the temperature of the refrigerant in the area A and all the other areas A by respective coefficients. For example, the prediction model can be expressed by a thermal network method or a polynomial approximation model as a calculation formula such as the following Equation (1).

$$[ \begin{matrix}{T}_{1} \\ ⋮ \\ {T}_{n}\end{matrix} ] = [ \begin{matrix}{a}_{1 , 1} & … & {a}_{1 , n} \\ ⋮ & ⋱ & ⋮ \\ {a}_{n , 1} & … & {a}_{n , n}\end{matrix} ] [ \begin{matrix}{p}_{1} \\ ⋮ \\ {p}_{n}\end{matrix} ] + [ \begin{matrix}{b}_{1 , 1} & … & {b}_{1 , n} \\ ⋮ & ⋱ & ⋮ \\ {b}_{n , 1} & … & {b}_{n , n}\end{matrix} ] [ \begin{matrix}{T}_{1}^{′} \\ ⋮ \\ {T}_{n}^{′}\end{matrix} ] + [ \begin{matrix}{c}_{1 , 1} & … & {c}_{1 , n} \\ ⋮ & ⋱ & ⋮ \\ {c}_{n , 1} & … & {c}_{n , n}\end{matrix} ] [ \begin{matrix}\frac{d}{dt} {T}_{1}^{′} \\ ⋮ \\ \frac{d}{dt} {T}_{n}^{′}\end{matrix} ] + [ \begin{matrix}{d}_{1 , 1} & … & {d}_{1 , n} \\ ⋮ & ⋱ & ⋮ \\ {d}_{n , 1} & … & {d}_{n , n}\end{matrix} ] [ \begin{matrix}{T}_{1}^{″} \\ ⋮ \\ {T}_{n}^{″}\end{matrix} ] + [ \begin{matrix}{e}_{1 , 1} & … & {e}_{1 , n} \\ ⋮ & ⋱ & ⋮ \\ {e}_{n , 1} & … & {e}_{n , n}\end{matrix} ] [ \begin{matrix}\frac{d}{dt} {T}_{1}^{″} \\ ⋮ \\ \frac{d}{dt} {T}_{n}^{″}\end{matrix} ] \qquad ( 1 )$$

Where,
n denotes a number sequentially assigned to each area A.
T₁ to Tₙ denote temperatures of the substrates W in the areas A numbered 1 to n, respectively.
p₁ to pₙ denote heating values of the heaters HT in the areas A numbered 1 to n, respectively.
T″₁ to T′ₙ denote temperatures of the body 111 in the areas A numbered 1 to n, respectively.
T″₁ to T″ₙ denote temperatures of the refrigerant in the areas A numbered 1 to n, respectively.
a_{1, 1} to a_{n, n} are coefficients for the heating values p₁ to pₙ of the heaters HT.
b_{1,1} to b_{n, n} are coefficients for the temperatures T′₁ to T′ₙ of the body 111.
c_{1, 1} to c_{n, n} are coefficients for the time derivatives of the temperatures T′₁ to T′ₙ of the body 111.
d_{1, 1} to d_{n, n} are coefficients for the temperatures T″₁ to T″ₙ of the refrigerant.
e_{1, 1} to e_{n, n} are coefficients for the time derivatives of the temperatures T″₁ to T″ₙ of the refrigerant.

The flow of heat in a part related to the substrate W and the body 111 can be expressed as a thermal circuit by the thermal network method. FIG. 5 is a diagram illustrating an example of a thermal circuit representing the substrate W and the body 111 according to the embodiment.

In the thermal circuit illustrated in FIG. 5, portions of the substrate W in the areas A numbered 1 to n are represented as nodes #1 to #n, respectively, portions of the body 111 in the areas A numbered 1 to n are represented as nodes #n+1 to #2n, respectively, and portions of the refrigerant in the flow path 1110a are represented as nodes #2n+1 to #3n, respectively. The refrigerant flows in the flow path 1110a. The heat transferred to the refrigerant flows together with the refrigerant. Therefore, the nodes #2n+1 to #3n are indicated as constant potential points using ground symbols.

The plasma processing apparatus 1 transfers heat between the substrate W and the body 111 and between the body 111 and the refrigerant in the flow path 1110a depending on the temperature difference for each area A. In the thermal circuit illustrated in FIG. 5, the thermal resistance between the substrate W and the body 111 is denoted as a thermal resistance R1, and the thermal resistance between the body 111 and the refrigerant in the flow path 1110a is denoted as a thermal resistance R2.

In addition, the plasma processing apparatus 1 transfers heat to the substrate W and the body 111 between the areas A depending on the temperature difference. In the thermal circuit illustrated in FIG. 5, the thermal resistance between the areas A of the substrate W is denoted as a thermal resistance R3, and the thermal resistance between the areas A of the body 111 is denoted as a thermal resistance R4.

In the plasma processing apparatus 1, a heater HT is provided in the body 111 for each area A, and the heating values of the heaters HT are transmitted to the body 111. In the thermal circuit illustrated in FIG. 5, a variable heat source P1 representing a heater HT is connected to each of the nodes #n+1 to #2n representing the body 111.

In addition, the plasma processing apparatus 1 inputs heat to the substrate W from a heat source such as plasma or a heated component in the plasma processing chamber 10 for each area A. In the thermal circuit illustrated in FIG. 5, the heat sources of the areas A numbered 1 to n are represented as variable heat sources P2. Note that the thermal circuit illustrated in FIG. 5 illustrates a state in which there is no heat input from the variable heat sources P2 to the areas A, and illustrates a separated state in which the variable heat sources P2 and the nodes #1 to #n in the areas A are separated from each other in the circuit. In a case where heat input from the variable heat sources P2 to the areas A is taken into consideration, the variable heat sources P2 and the nodes #1 to #n in the areas A are connected in the circuit.

Simultaneous equations of the heat balance for the nodes #1 to #3n can be expressed as the following Equations (2-1) to (2-3n).

$$\{ \begin{matrix}{Q}_{1} + \sum {G}_{1 , i} ( {T}_{i} - {T}_{1} ) = {C}_{1} \frac{{dT}_{1}}{dt} & … ( 2 - 1 ) \\ \\ {Q}_{2} + \sum {G}_{2 , i} ( {T}_{i} - {T}_{2} ) = {C}_{2} \frac{{dT}_{2}}{dt} & … ( 2 - 2 ) \\ \\ ⋮ & ⋮ \\ {Q}_{3 n} + \sum {G}_{3 n , i} ( {T}_{i} - {T}_{3 n} ) = {C}_{3 n} \frac{{dT}_{3 n}}{dt} & … ( 2 - 3 n ) \\\end{matrix}$$

Where,
Q denotes the amount of heat input (W) at a node. For example, Q₁ denotes the heat input amount at the node #1.
G denotes a thermal conductivity (W/K) between nodes. For example, G_{1, i} denotes the thermal conductivity between the node #1 and the node #i.
T denotes the temperature (deg C.) of a node. For example, T₁ denotes the temperature of the node #1.
t denotes time (sec).
C denotes the heat capacity of a node. For example, C₁ denotes the heat capacity of the node #1.

In the left sides of the equations of the simultaneous equations of the heat balance, for each of the nodes, i is set to 1 to 3n, the temperature differences between the node and the nodes #1 to #3n are each multiplied by the thermal conductivity G, products of which are added up, and the heat input amount Q and the sum are added. For example, in the left side of the Equation (2-1), for the node #1, with i as 1 to 3n, temperature differences (Tᵢ−T₁) between the node #1 and the nodes #1 to #3n are each multiplied by the thermal conductivity G_{1, i,} products of which are added up, and the heat input amount Q₁ and the sum are added.

Equations (2-1) to (2-3n) contain a term of heat transfer between all the nodes #1 to #3n. As for nodes between which heat transfer is not considered, the thermal conductivity G between the nodes is set to zero, for example. For example, between nodes not connected by the thermal circuit illustrated in FIG. 5, the thermal conductivity G between the nodes is set to, for example, zero.

For example, simultaneous equations of the heat balance for the node #1 illustrated in FIG. 5 can be expressed as the following Equation (3).

$${Q}_{1} = {C}_{1} \frac{{dT}_{1}}{dt} - {G}_{1 , 2} ( {T}_{2} - {T}_{1} ) - … - {G}_{1 , n} ( {T}_{n} - {T}_{1} ) - {G}_{1 , n + 1} ( {T}_{n + 1} - {T}_{1} ) \qquad ( 3 )$$

The above Equation (1) can be obtained from such simultaneous equations of the heat balance for the nodes #1 to #3n. Also in a case where a polynomial approximation model is used, the above Equation (1) can be similarly obtained.

The values of the coefficients a_{1, 1} to a_{n, n}, b_{1, 1} to b_{n, n}, c_{1, 1} to c_{n, n}, d_{1, 1} to d_{n, n}, and e_{1, 1} to e_{n, n} in Equation (1) can be determined by performing fitting using data for fitting. The data for fitting is generated by obtaining a relationship among the temperature of the substrate W in each area A, the heating value of the heater HT, the temperature of the body 111, the temperature of the refrigerant, the time derivative of the temperature of the body 111, and the time derivative of the temperature of the refrigerant by the plasma processing apparatus 1.

For example, when data for fitting is generated, the substrate W is placed on the central region 111a of the substrate support unit 11. When the data for fitting is generated, the process controller 104 controls the heater power supply 60 to cause each heater HT to generate heat while performing cooling by circulating the refrigerant from the chiller unit 14 to the flow path 1110a in a state where no plasma is generated. The process controller 104 measures the temperature of the substrate W, the heating value of the heater HT, the temperature of the body 111, and the temperature of the refrigerant in each area A. The temperature of the substrate W in each area A is measured, for example, by disposing a temperature sensor such as an infrared camera in the plasma processing chamber 10. In addition, the temperature of the substrate W in each area A is measured using, for example, a sensor substrate capable of measuring the temperature. The process controller 104 periodically measures the temperature of the substrate W, the heating value of the heater HT, the temperature of the body 111, and the temperature of the refrigerant in each area A, including a transitional period in which the temperature is changing, for a plurality of various patterns by changing the temperature of the refrigerant and the heating value of each heater HT. The process controller 104 generates data for fitting in which the temperature of the substrate W, the heating value of the heater HT, the temperature of the body 111, and the temperature of the refrigerant in each area A are stored together with measurement time.

The temperature of the refrigerant in each area A may be substituted by the temperature of the refrigerant measured by the chiller unit 14.

Incidentally, the temperature of the refrigerant flowing through the flow path 1110a gradually increases due to heat input from the base 1110. Therefore, the temperature of the refrigerant in each area A of the data for fitting may be corrected depending on the temperature increase along the flow path 1110a. For example, the amount of increase in the temperature of the refrigerant when the refrigerant passes through the flow path 1110a is obtained. In addition, the total length from one end of the flow path 1110a into which the refrigerant flows to the other end from which the refrigerant flows out is obtained. The length of the flow path 1110a to each area A is obtained. The length of the flow path 1110a to each area A is measured along the flow path 1110a from one end. The total length of the flow path 1110a and the length of the flow path 1110a to each area A may be obtained from design data of the base 1110, or the base 1110 may actually be measured. In the correction of the temperature of the refrigerant, the amount of increase in the temperature of the refrigerant in each area A is calculated by, for each area A, multiplying the amount of increase in the temperature of the refrigerant over the entire length of the flow path 1110a by the ratio of the length of the flow path 1110a up to the area A to the entire length of the flow path 1110a. In the correction of the temperature of the refrigerant, for each area A, the temperature of the refrigerant in the area A is calculated by adding the amount of increase in the temperature of the refrigerant calculated for the area A to the temperature of the refrigerant measured by the thermometer installed in the chiller unit 14 or a pipe 14a. The amount of increase in the temperature of the refrigerant for each area A may be obtained by simulation or the like.

By performing fitting of Equation (1) using such data for fitting, appropriate values can be specified for the coefficients a_{1, 1} to a_{n, n}, b_{1, 1} to b_{n, n}, c_{1, 1} to c_{n, n}, d_{1, 1} to d_{n, n}, and e_{1, 1} to e_{n, n}.

The prediction model data 110 stores Equation (1) in which the specified values are set to the coefficients a_{1, 1} to a_{n, n}, b_{1, 1} to b_{n, n}, c_{1, 1} to c_{n, n}, d_{1, 1} to d_{n, n}, and e_{1, 1} to e_{n, n}.

The acquisition unit 121 periodically acquires the heating value of each heater HT, the temperature of the body 111, and the temperature of the refrigerant. In the present embodiment, the acquisition unit 121 periodically acquires the temperature of the refrigerant, the heating value of a heater HT for each area A, and the temperature of the body 111. The cycle in which the acquisition unit 121 acquires the temperature of the refrigerant, the heating values of the heaters HT, and the temperature of the body 111 may be any cycle as long as the time derivative of the temperature of the body 111 and the time derivative of the temperature of the refrigerant can be obtained. For example, the cycle is preferably a 0.01 to 0.1 second cycle, and more preferably a 0.0001 to 0.01 second cycle.

The correction unit 122 corrects the temperature of the refrigerant acquired by the acquisition unit 121 to a temperature of the refrigerant in each area A corresponding to the temperature rise along the flow path 1110a. For example, for each area A, the correction unit 122 calculates the amount of increase in the temperature of the refrigerant for each area A by multiplying the amount of increase in the temperature of the refrigerant over the entire length of the flow path 1110a by the ratio of the length of the flow path 1110a to the area A to the entire length of the flow path 1110a. Then, the correction unit 122 adds the amount of increase in the temperature of the refrigerant calculated in each area A to the temperature of the refrigerant measured by the thermometer installed in the chiller unit 14 or the pipe 14a for each area A to calculate the temperature of the refrigerant for each area A. Note that the correction unit 122 may calculate the temperature of the refrigerant in each area A by adding the amount of increase in the temperature of the refrigerant in each area A obtained by simulation or the like to the temperature of the refrigerant measured by the thermometer installed in the chiller unit 14 or the pipe 14a.

The prediction unit 123 predicts the temperature of the substrate W for each area A using the prediction model stored in the prediction model data 110. The prediction unit 123 predicts the temperature of the substrate W for each area A using Equation (1) from the corrected temperature of the refrigerant in each area A, the acquired heating value of the heater HT in each area A, the temperature of the body 111, the time derivative of the temperature of the body 111, and the time derivative of the temperature of the refrigerant using Equation (1). For example, the prediction unit 123 substitutes the temperature of the refrigerant in each area A, the heating values of the heaters HT, the temperature of the body 111, the time derivative of the temperature of the body 111, and the time derivative of the temperature of the refrigerant into Equation (1) to calculate the temperature of the substrate W in each area A. The prediction unit 123 can accurately predict the temperature of the substrate W by using Equation (1).

The heat generation controller 124 controls the heating values of the heaters HT such that the temperature of the substrate W predicted by the prediction unit 123 becomes a predetermined temperature. A set temperature of the substrate W is set in the heat generation controller 124. The heat generation controller 124 controls the heating values of the heaters HT such that the temperature of the substrate W predicted by the prediction unit 123 becomes the set temperature. For example, at the time of plasma processing, in the heat generation controller 124, the set temperature of the substrate W stored in the recipe is set for each area A of the substrate W. The heat generation controller 124 controls the heating values of the heaters HT such that the temperature of the substrate W becomes the set temperature for each area A. For example, the heat generation controller 124 controls the heater power supply 60 in such a manner as to increase the heating value of a heater HT in an area A where the predicted temperature of the substrate W is lower than the set temperature and to decrease the heating value of a heater HT in an area A where the predicted temperature of the substrate W is higher than the set temperature. For example, the heat generation controller 124 outputs, to the heater power supply 60, control data for increasing the duty ratio of an area A where the predicted temperature of the substrate W is lower than the set temperature and decreasing the duty ratio of an area A where the predicted temperature of the substrate W is higher than the set temperature.

### Specific Example of Flow of Substrate Temperature Controlling Process

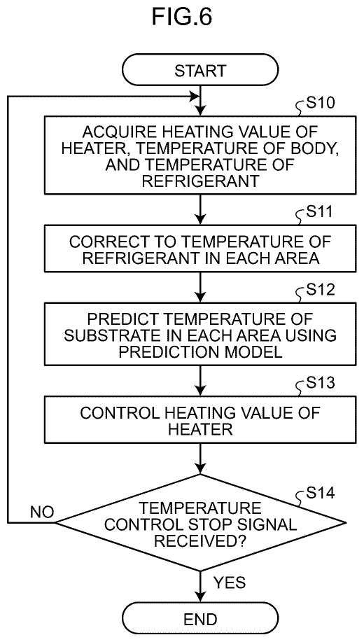

Next, a specific example of the flow of a substrate temperature controlling process including the substrate temperature control method according to the embodiment will be described. FIG. 6 is a flowchart illustrating an example of the flow of the substrate temperature controlling process according to the embodiment. The substrate temperature controlling process according to the embodiment is executed when the plasma processing is started. When the plasma processing is started, in the heat generation controller 124, the set temperature of the substrate W stored in the recipe is set for each area A of the substrate W.

The acquisition unit 121 acquires the heating values of the heaters HT, the temperature of the body 111, and the temperature of the refrigerant (step S10). For example, the acquisition unit 121 acquires the temperature of the refrigerant, the heating value of the heater HT in each area A, and the temperature of the body 111.

The correction unit 122 corrects the temperature of the refrigerant acquired by the acquisition unit 121 to the temperature of the refrigerant in each area A (step S11).

The prediction unit 123 predicts the temperature of the substrate W in each area A using the prediction model stored in the prediction model data 110 (step S12). For example, the prediction unit 123 predicts the temperature of the substrate W in each area A from the temperature of the refrigerant in each area A corrected using Equation (1), the acquired heating value of the heater HT in each area A, the temperature of the body 111, the time derivative of the temperature of the body 111, and the time derivative of the temperature of the refrigerant.

The heat generation controller 124 controls the heating values of the heaters HT such that the temperature of the substrate W predicted by the prediction unit 123 becomes the set temperature for each area A (step S13).

The heat generation controller 124 determines whether or not a temperature control stop signal instructing to stop the temperature control has been received (step S14). If the temperature control stop signal has not been received (step S14: No), the process proceeds to step S10 described above. If the temperature control stop signal has been received (step S14: Yes), the process ends. The substrate temperature controlling process continues until a temperature control stop signal is received even when the plasma processing is completed.

As a result, the plasma processing apparatus 1 according to the embodiment can accurately control the temperature of each area A of the substrate W to the set temperature.

Note that, in the above embodiment, the case where the prediction model includes, for each area A, a term of heat transfer from the area A and all the other areas A has been described as an example. However, the present disclosure is not limited thereto. For example, the prediction model may include, for each area A, a term of heat transfer from the area A and some of the other areas A. Some of the other areas A are only preferred to be an area A in which heat transfer to the area A occurs, and may be an area A around the area A, or may be an area A adjacent to the area A.

In the above embodiment, the case has been described as an example where the temperature of the substrate W is predicted for each area A obtained by dividing the central region 111a of the body 111, and the heating value of the heater HT is controlled for each area A such that the temperature of the substrate W becomes the set temperature. However, the present disclosure is not limited thereto. For example, instead of dividing the central region 111a of the body 111 into the areas A, the temperature of the substrate W may be predicted with the central region 111a as one area A, and the heating value of a heater HT may be controlled such that the temperature of the substrate W becomes a set temperature.

In the above embodiment, the thermal circuit having the configuration of FIG. 5 has been illustrated as a thermal circuit representing the substrate W and the body 111. However, the present disclosure is not limited thereto. In the thermal circuit representing the substrate W and the body 111, a node may be added in consideration of heat transfer between a temperature sensor TS and a heater HT in the body 111. For example, the thermal circuit representing the substrate W and the body 111 may have a circuit configuration in which nodes are added between the nodes #1 to #n and the nodes #n+1 to #2n, respectively, of the thermal circuit having the configuration of FIG. 5, and the nodes are connected to nodes to which variable heat sources P1 each representing a heater HT are added.

In the above embodiment, the case where the prediction model (Equation (1)) obtained from the data for fitting generated by the plasma processing apparatus 1 is stored in the prediction model data 110 has been described as an example. However, the present disclosure is not limited thereto. The prediction model of the prediction model data 110 may store a prediction model obtained by another plasma processing apparatus. For example, in the case of operating a plurality of plasma processing apparatuses, any of the plasma processing apparatuses may specify the coefficients a_{1, 1} to a_{n, n}, b_{1, 1} to b_{n, n}, c_{1, 1} to c_{n, n}, d_{1, 1} to d_{n, n}, and e_{1, 1} to e_{n, n} to obtain Equation (1), and use the obtained Equation (1) in the plurality of plasma processing apparatuses. Furthermore, the prediction model of the prediction model data 110 may be provided by the manufacturer of the plasma processing apparatus. The prediction model may be capable of adjusting an individual difference for each plasma processing apparatus. For example, a correction term may be added to Equation (1) in order to absorb an individual difference of a plasma processing apparatus. Each plasma processing apparatus 1 may use a prediction model in which a correction term is adjusted depending on an individual difference of each plasma processing apparatus 1. For example, Equation (1) to be used as a standard in a plasma processing apparatus as a standard is obtained. Each plasma processing apparatus 1 stores Equation (1) obtained by adjusting the correction term in prediction model data 110 as the prediction model.

In the above embodiment, the case where the plasma processing is performed on the semiconductor wafer as the substrate W has been described as an example, but the present disclosure is not limited thereto. The substrate W may be any substrate.

In the above embodiment, the case where the substrate processing apparatus is used as the plasma processing system that performs a plasma etching process has been described as an example. However, the present disclosure is not limited thereto. The substrate processing apparatus may be any apparatus as long as a heat source that inputs heat to the substrate W emerges. For example, the substrate processing apparatus may be a film forming apparatus that generates plasma to form a film. In addition, the substrate processing apparatus may be a heat treatment apparatus that performs heat treatment such as ashing on the substrate W by a heat source such as a light source or a heater.

As described above, the plasma processing system (substrate processing apparatus) according to the embodiment includes the body 111 (stage), the plasma processing chamber 10 (chamber), the cooling mechanism (refrigerant, flow path 1110a, and others), the heater HT (heating mechanism), the temperature sensor TS (measurement unit), the acquisition unit 121, the prediction unit 123, and the heat generation controller 124. The substrate W is placed on the body 111. The plasma processing chamber 10 is provided with the body 111 therein, and a heat source that inputs heat to the substrate W placed on the body 111 emerges. The cooling mechanism is provided to the body 111 and cools the body 111. The heater HT is provided between the central region 111a (placement surface) of the body 111 on which the substrate W is placed and the cooling mechanism, is capable of controlling the heating value, and heats the body 111. The temperature sensor TS measures the temperature of the body 111. The acquisition unit 121 periodically acquires the heating values of the heaters HT, the temperature of the body 111, and the temperature of the cooling mechanism. The prediction unit 123 predicts the temperature of the substrate W from the heating value of the heater HT, the temperature of the body 111, and the temperature of the cooling mechanism acquired by the acquisition unit 121, the time derivative of the temperature of the body 111, and the time derivative of the temperature of the cooling mechanism by using the calculation formula (for example, Equation (1)) that predicts the temperature of the substrate W from the heating value of the heater HT, the temperature of the body 111, the temperature of the cooling mechanism, the time derivative of the temperature of the body 111, and the time derivative of the temperature of the cooling mechanism. The heat generation controller 124 controls the heating values of the heaters HT such that the temperature of the substrate W predicted by the prediction unit 123 becomes a predetermined temperature. As a result, the plasma processing system according to the embodiment can accurately control the temperature of the substrate W.

In addition, the calculation formula is a prediction model that calculates the temperature of the substrate W by adding up products obtained by multiplying the heating value of the heater HT, the temperature of the body 111, the temperature of the cooling mechanism, the time derivative of the temperature of the body 111, and the time derivative of the temperature of the cooling mechanism by respective coefficients. As a result, the plasma processing system according to the embodiment can predict the temperature of the substrate W by the prediction model, and thus can accurately control the temperature of the substrate W.

In addition, the calculation formula is a mathematical model that calculates the temperature of the substrate W by adding up products obtained by multiplying the heating value of the heater HT, the temperature of the body 111, the temperature of the cooling mechanism, the time derivative of the temperature of the body 111, and the time derivative of the temperature of the cooling mechanism by respective coefficients. The value of each of the coefficients of the mathematical model is determined using data obtained in advance for a relationship among the temperature of the substrate W, the heating value of the heater HT, the temperature of the body 111, the temperature of the cooling mechanism, the time derivative of the temperature of the body 111, and the time derivative of the temperature of the cooling mechanism. As a result, the plasma processing system according to the embodiment can predict the temperature of the substrate W by the mathematical model, and thus can accurately control the temperature of the substrate W.

In addition, the value of each of the coefficients of the mathematical model is determined by performing fitting using the data. As a result, the plasma processing system according to the embodiment can predict the temperature of the substrate W by the mathematical model, and thus can accurately control the temperature of the substrate W.

In the body 111, the central region 111a on which the substrate W is placed is divided into the plurality of areas A. The cooling mechanism is provided in all the areas A of the body 111. A heater HT is provided for each area A of the body 111. A temperature sensor TS is provided for each area A of the body 111, and measures the temperature of the body 111 for each area A. The acquisition unit 121 periodically acquires the temperature of the cooling mechanism, and the heating value of a heater HT and the temperature of the body 111 in each area A. The prediction unit 123 predicts the temperature of the substrate W in each area A from the temperature of the cooling mechanism, the heating value of the heater HT, and the temperature of the body 111 in each area A acquired by the acquisition unit 121, the time derivative of the temperature of the body 111 in each area A and the time derivative of the temperature of the cooling mechanism using the calculation formula. As a result, the plasma processing system according to the embodiment can predict the temperature of the substrate W in each area A, and thus can accurately control the temperature of the substrate W in each area A.

In addition, the calculation formula is a mathematical model that calculates the temperature of the substrate W in the area A by, for each area A, adding up products obtained by multiplying of the heating values of the heaters HT, the temperature of the body 111, the temperature of the cooling mechanism, the time derivative of the temperature of the body 111, and the time derivative of the temperature of the cooling mechanism in the area A and the other areas A by respective coefficients. The value of each of the coefficients of the mathematical model is determined using data obtained in advance for a relationship among the temperature of the substrate W, the heating value of the heater HT, the temperature of the body 111, the temperature of the cooling mechanism, the time derivative of the temperature of the body 111, and the time derivative of the temperature of the cooling mechanism in each area A. As a result, the plasma processing system according to the embodiment can predict the temperature of the substrate W in each area A in consideration of heat transfer to other areas A by the mathematical model, and thus can accurately control the temperature of the substrate W in each area A.

In addition, the value of each of the coefficients of the mathematical model is determined by performing fitting using the data. As a result, the plasma processing system according to the embodiment can predict the temperature of the substrate W in each area A by the mathematical model, and thus can accurately control the temperature of the substrate W in each area A.

In addition, the calculation formula is a mathematical model that calculates the temperature of the substrate W in the area A by, for each area A, adding up products obtained by multiplying the heating values of the heaters HT, the temperature of the body 111, the temperature of the cooling mechanism, the time derivative of the temperature of the body 111, and the time derivative of the temperature of the cooling mechanism in the area A and all the other areas A by respective coefficients. As a result, the plasma processing system according to the embodiment can predict the temperature of the substrate W in each area A in consideration of heat transfer to all the other areas A by the mathematical model, and thus can accurately control the temperature of the substrate W in each area A.

The cooling mechanism is formed to pass through all the areas A of the body 111, and is a flow path 1110a through which the refrigerant flows. The correction unit 122 obtains the temperature of the refrigerant flowing into the flow path 1110a. The plasma processing system according to the embodiment further includes the correction unit 122. The correction unit 122 corrects the temperature of the refrigerant acquired by the acquisition unit 121 to the temperature of the refrigerant in each area A along the flow path 1110a. The prediction unit 123 predicts the temperature of the substrate W in each area A from the temperature of the refrigerant in each area A corrected by the correction unit 122, the heating value of the heater HT and the temperature of the body 111 in each area A acquired by the acquisition unit 121, and the time derivatives of the temperature of the cooling mechanism and the temperature of the body 111 in each area A using the calculation formula for each area A. As a result, the plasma processing system according to the embodiment can predict the temperature of the substrate W in each area A using the temperature of the refrigerant in the area A, and thus can accurately control the temperature of each area A.

The prediction unit 123 predicts the temperature of the substrate W in a state where a heat source has emerged. The heat source is either plasma or a heated component in the plasma processing chamber 10. As a result, the plasma processing system according to the embodiment can predict the temperature of the substrate W that receives heat input from the heat source, and thus can accurately control the temperature of the substrate W that receives heat input from the heat source.

Note that the embodiments disclosed herein are to be considered in all respects as illustrative and not restrictive. Indeed, the embodiments described above may be embodied in various forms. The above embodiments may be omitted, replaced, or modified in various forms without departing from the scope and the gist of the appended claims.

Regarding the above embodiments, the following supplementary notes are further disclosed.

According to the present disclosure, the temperature of a substrate can be accurately controlled.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112 (f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

In connection with the above embodiment, the following notes are further disclosed.

### (Note 1)

A substrate processing apparatus comprising:
a stage on which a substrate is placed;
a chamber in which the stage is provided and a heat source that inputs heat to the substrate placed on the stage emerges;
a cooling mechanism that is provided on the stage and cools the stage;
a heating mechanism that heats the stage, the heating mechanism provided between a placement surface of the stage on which the substrate is placed and the cooling mechanism, the heating mechanism capable of controlling a heating value;
a measurement unit that measures a temperature of the stage;
an acquisition unit that periodically acquires a heating value of the heating mechanism, the temperature of the stage, and a temperature of the cooling mechanism;
a prediction unit that predicts, from the heating value of the heating mechanism, the temperature of the stage, and the temperature of the cooling mechanism acquired by the acquisition unit, a time derivative of the temperature of the stage, and a time derivative of the temperature of the cooling mechanism, a temperature of the substrate by using a calculation formula for predicting the temperature of the substrate from the heating value of the heating mechanism, the temperature of the stage, the temperature of the cooling mechanism, the time derivative of the temperature of the stage, and the time derivative of the temperature of the cooling mechanism; and
a heat generation controller that controls the heating value of the heating mechanism such that the temperature of the substrate predicted by the prediction unit becomes a predetermined temperature.

### (Note 2)

The substrate processing apparatus according to note 1, wherein
the calculation formula is a prediction model that predicts the temperature of the substrate from the heating value of the heating mechanism, the temperature of the stage, the temperature of the cooling mechanism, the time derivative of the temperature of the stage, and the time derivative of the temperature of the cooling mechanism.

### (Note 3)

The substrate processing apparatus according to note 1 or 2, wherein
the calculation formula is a mathematical model that calculates the temperature of the substrate by adding up products obtained by multiplying the heating value of the heating mechanism, the temperature of the stage, the temperature of the cooling mechanism, the time derivative of the temperature of the stage, and the time derivative of the temperature of the cooling mechanism by respective coefficients, and
a value of each of the coefficients of the mathematical model is determined using data obtained in advance for a relationship among the temperature of the substrate, the heating value of the heating mechanism, the temperature of the stage, the temperature of the cooling mechanism, the time derivative of the temperature of the stage, and the time derivative of the temperature of the cooling mechanism.

### (Note 4)

The substrate processing apparatus according to note 3, wherein
the value of each of the coefficients of the mathematical model is determined by performing fitting using the data.

### (Note 5)

The substrate processing apparatus according to note 1, wherein
the placement surface is divided into a plurality of areas in the stage,
the cooling mechanism is provided in all the areas of the stage,
the heating mechanism is provided in each of the areas of the stage,
the measurement unit is provided in each of the areas of the stage, and measures the temperature of the stage for each of the areas,
the acquisition unit periodically acquires the temperature of the cooling mechanism and, for each of the areas, the heating value of the heating mechanism and the temperature of the stage, and
the prediction unit predicts the temperature of the substrate in each of the areas from the temperature of the cooling mechanism, the heating value of the heating mechanism and the temperature of the stage in each of the areas obtained by the acquisition unit, and the time derivative of the temperature of the stage in each of the areas and the time derivative of the temperature of the cooling mechanism using the calculation formula.

### (Note 6)

The substrate processing apparatus according to note 5, wherein
the calculation formula is a mathematical model that calculates the temperature of the substrate in each of the areas by, for each of the areas, adding up products obtained by multiplying the heating value of the heating mechanism, the temperature of the stage, the temperature of the cooling mechanism, the time derivative of the temperature of the stage, and the time derivative of the temperature of the cooling mechanism in the area and other areas by respective coefficients, and
a value of each of the coefficients of the mathematical model is determined using data obtained in advance for a relationship among the temperature of the substrate in each of the areas, the heating value of the heating mechanism, the temperature of the stage, the temperature of the cooling mechanism, the time derivative of the temperature of the stage, and the time derivative of the temperature of the cooling mechanism.

### (Note 7)

The substrate processing apparatus according to note 6, wherein
the value of each of the coefficients of the mathematical model is determined by performing fitting using the data.

### (Note 8)

The substrate processing apparatus according to note 6 or 7, wherein
the calculation formula is a mathematical model that calculates the temperature of the substrate in each of the areas A by, for each of the areas, adding up products obtained by multiplying the heating value of the heating mechanism, the temperature of the stage, the temperature of the cooling mechanism, the time derivative of the temperature of the stage, and the time derivative of the temperature of the cooling mechanism in the area and all the other areas by respective coefficients.

### (Note 9)

The substrate processing apparatus according to any one of notes 5 to 8, wherein
the cooling mechanism is a flow path formed to pass through all of the areas of the stage and through which a refrigerant flows, and
the acquisition unit acquires a temperature of the refrigerant flowing into the flow path.

### (Note 10)

The substrate processing apparatus according to note 9, further comprising:
a correction unit that corrects the temperature of the refrigerant acquired by the acquisition unit to a temperature of the refrigerant in each of the areas along the flow path, wherein
the prediction unit predicts the temperature of the substrate in each of the areas from the temperature of the refrigerant in each of the areas corrected by the correction unit, the heating value of the heating mechanism and the temperature of the stage in each of the areas acquired by the acquisition unit, and the time derivatives of the temperature of the cooling mechanism and the temperature of the stage in each of the areas using the calculation formula.

### (Note 11)

The substrate processing apparatus according to any one of notes 1 to 10, wherein
the prediction unit predicts the temperature of the substrate in a state where the heat source has emerged.

### (Note 12)

The substrate processing apparatus according to any one of notes 1 to 11, wherein
the heat source is at least one of plasma or a heated component in the chamber.

### (Note 13)

A substrate temperature control method of a substrate processing apparatus including:
a stage on which a substrate is placed;
a chamber in which the stage is provided and a heat source that inputs heat to the substrate placed on the stage emerges;
a cooling mechanism that is provided on the stage and cools the stage;
a heating mechanism that heats the stage, the heating mechanism provided between a placement surface of the stage on which the substrate is placed and the cooling mechanism, the heating mechanism capable of controlling a heating value; and
a measurement unit that measures a temperature of the stage, the substrate temperature control method comprising:
a) a step of periodically acquiring a heating value of the heating mechanism, the temperature of the stage, and a temperature of the cooling mechanism;
b) a step of predicting, from the heating value of the heating mechanism, the temperature of the stage, and the temperature of the cooling mechanism having been acquired, a time derivative of the temperature of the stage, and a time derivative of the temperature of the cooling mechanism, a temperature of the substrate by using a calculation formula for predicting the temperature of the substrate from the heating value of the heating mechanism, the temperature of the stage, the temperature of the cooling mechanism, the time derivative of the temperature of the stage, and the time derivative of the temperature of the cooling mechanism; and
c) a step of controlling the heating value of the heating mechanism such that the temperature of the substrate to be predicted becomes a predetermined temperature.

What is claimed is:

1. A substrate processing apparatus comprising:
a stage that supports a substrate;
a chamber in which the stage is located and a heat source that inputs heat to the substrate placed on the stage;
a cooling structure that is located on the stage and cools the stage;
a heater that heats the stage, the heater is located between a placement surface of the stage on which the substrate is placed and the cooling structure, the heater to control a heating value;
a temperature sensor that measures a temperature of the stage;
acquisition circuitry that periodically acquires a heating value of the heater, the temperature of the stage, and a temperature of the cooling structure;
prediction circuitry that predicts, from the heating value of the heater, the temperature of the stage, and the temperature of the cooling structure acquired by the acquisition circuitry, a time derivative of the temperature of the stage, and a time derivative of the temperature of the cooling structure, a temperature of the substrate by using a calculation formula for predicting the temperature of the substrate from the heating value of the heater, the temperature of the stage, the temperature of the cooling structure, the time derivative of the temperature of the stage, and the time derivative of the temperature of the cooling structure; and
heat generation controller circuitry that controls the heating value of the heater such that the temperature of the substrate predicted by the prediction circuitry becomes a predetermined temperature.

2. The substrate processing apparatus according to claim 1, wherein
the calculation formula is a prediction model that predicts the temperature of the substrate from the heating value of the heater, the temperature of the stage, the temperature of the cooling structure, the time derivative of the temperature of the stage, and the time derivative of the temperature of the cooling structure.

3. The substrate processing apparatus according to claim 1, wherein
the calculation formula is a mathematical model that calculates the temperature of the substrate by adding up products obtained by multiplying the heating value of the heater, the temperature of the stage, the temperature of the cooling structure, the time derivative of the temperature of the stage, and the time derivative of the temperature of the cooling structure by respective coefficients, and
a value of each of the coefficients of the mathematical model is determined using data obtained in advance for a relationship among the temperature of the substrate, the heating value of the heater, the temperature of the stage, the temperature of the cooling structure, the time derivative of the temperature of the stage, and the time derivative of the temperature of the cooling structure.

4. The substrate processing apparatus according to claim 3, wherein
the value of each of the coefficients of the mathematical model is determined by performing fitting using the data.

5. The substrate processing apparatus according to claim 1, wherein
the placement surface is divided into a plurality of areas in the stage,
the cooling structure is located in all the areas of the stage,
the heater is located in each of the areas of the stage,
the temperature sensor is located in each of the areas of the stage, and measures the temperature of the stage for each of the areas,
the acquisition circuitry periodically acquires the temperature of the cooling structure and, for each of the areas, the heating value of the heater and the temperature of the stage, and
the prediction circuitry predicts the temperature of the substrate in each of the areas from the temperature of the cooling structure, the heating value of the heater and the temperature of the stage in each of the areas obtained by the acquisition circuitry, and the time derivative of the temperature of the stage in each of the areas and the time derivative of the temperature of the cooling structure using the calculation formula.

6. The substrate processing apparatus according to claim 5, wherein
the calculation formula is a mathematical model that calculates the temperature of the substrate in each of the areas by, for each of the areas, adding up products obtained by multiplying the heating value of the heater, the temperature of the stage, the temperature of the cooling structure, the time derivative of the temperature of the stage, and the time derivative of the temperature of the cooling structure in the area and other areas by respective coefficients, and
a value of each of the coefficients of the mathematical model is determined using data obtained in advance for a relationship among the temperature of the substrate in each of the areas, the heating value of the heater, the temperature of the stage, the temperature of the cooling structure, the time derivative of the temperature of the stage, and the time derivative of the temperature of the cooling structure.

7. The substrate processing apparatus according to claim 6, wherein
the value of each of the coefficients of the mathematical model is determined by performing fitting using the data.

8. The substrate processing apparatus according to claim 6, wherein
the calculation formula is a mathematical model that calculates the temperature of the substrate in each of the areas A by, for each of the areas, adding up products obtained by multiplying the heating value of the heater, the temperature of the stage, the temperature of the cooling structure, the time derivative of the temperature of the stage, and the time derivative of the temperature of the cooling structure in the area and all the other areas by respective coefficients.

9. The substrate processing apparatus according to claim 5, wherein
the cooling structure is a flow path formed to pass through all of the areas of the stage and through which a refrigerant flows, and
the acquisition circuitry acquires a temperature of the refrigerant flowing into the flow path.

10. The substrate processing apparatus according to claim 9, further comprising:
correction circuitry that corrects the temperature of the refrigerant acquired by the acquisition circuitry to a temperature of the refrigerant in each of the areas along the flow path, wherein
the prediction circuitry predicts the temperature of the substrate in each of the areas from the temperature of the refrigerant in each of the areas corrected by the correction circuitry, the heating value of the heater and the temperature of the stage in each of the areas acquired by the acquisition circuitry, and the time derivatives of the temperature of the cooling structure and the temperature of the stage in each of the areas using the calculation formula.

11. The substrate processing apparatus according to claim 1, wherein
the prediction circuitry predicts the temperature of the substrate in a state where the heat source has emerged.

12. The substrate processing apparatus according to claim 1, wherein
the heat source is at least one of plasma or a heated component in the chamber.

13. A substrate temperature control method of a substrate processing apparatus, the substrate temperature control method comprising:
periodically acquiring a heating value of a heater that heats a stage, a temperature of the stage, and a temperature of a cooling structure, wherein the heater is located between a placement surface of the stage that supports a substrate and the cooling structure that is located on the stage and cools the stage;
predicting, from the heating value of the heater, the temperature of the stage, and the temperature of the cooling structure having been acquired, a time derivative of the temperature of the stage, and a time derivative of the temperature of the cooling structure, a temperature of the substrate by using a calculation formula for predicting the temperature of the substrate from the heating value of the heater, the temperature of the stage, the temperature of the cooling structure, the time derivative of the temperature of the stage, and the time derivative of the temperature of the cooling structure; and
controlling the heating value of the heater such that the temperature of the substrate to be predicted becomes a predetermined temperature.

14. The substrate processing apparatus according to claim 1, wherein
the calculation formula is a mathematical model that calculates the temperature of the substrate by adding up products obtained by multiplying the heating value of the heater, the temperature of the stage, the temperature of the cooling structure, the time derivative of the temperature of the stage, and the time derivative of the temperature of the cooling structure by respective coefficients.

15. The substrate processing apparatus according to claim 1, wherein
the placement surface is divided into a plurality of areas in the stage.

16. The substrate processing apparatus according to claim 1, wherein
the placement surface is divided into a plurality of areas in the stage, and
the cooling structure is located in all the areas of the stage.

17. The substrate processing apparatus according to claim 1, wherein
the placement surface is divided into a plurality of areas in the stage,
the cooling structure is located in all the areas of the stage, and
the heater is located in each of the areas of the stage.

18. The substrate processing apparatus according to claim 1, wherein
the placement surface is divided into a plurality of areas in the stage,
the cooling structure is located in all the areas of the stage,
the heater is located in each of the areas of the stage, and
the temperature sensor is located in each of the areas of the stage, and measures the temperature of the stage for each of the areas.

19. The substrate processing apparatus according to claim 5, wherein
the calculation formula is a mathematical model that calculates the temperature of the substrate in each of the areas by, for each of the areas, adding up products obtained by multiplying the heating value of the heater, the temperature of the stage, the temperature of the cooling structure, the time derivative of the temperature of the stage, and the time derivative of the temperature of the cooling structure in the area and other areas by respective coefficients.

20. A non-transitory computer-readable storage medium storing executable instructions, which when executed by controller circuitry, cause the controller circuitry to perform a method, the method comprising:
periodically acquiring a heating value of a heater that heats a stage, a temperature of the stage, and a temperature of a cooling structure, wherein the heater is located between a placement surface of the stage that supports a substrate and the cooling structure that is located on the stage and cools the stage;
predicting, from the heating value of the heater, the temperature of the stage, and the temperature of the cooling structure having been acquired, a time derivative of the temperature of the stage, and a time derivative of the temperature of the cooling structure, a temperature of the substrate by using a calculation formula for predicting the temperature of the substrate from the heating value of the heater, the temperature of the stage, the temperature of the cooling structure, the time derivative of the temperature of the stage, and the time derivative of the temperature of the cooling structure; and
controlling the heating value of the heater such that the temperature of the substrate to be predicted becomes a predetermined temperature.
